(19) United States
(12) Patent Application Publication
(10) Pub. No.: US 2025/0061252 A1
(43) Pub. Date: Feb. 20, 2025

(54) SKETCH ANALYSIS FOR GENERATIVE DESIGN VIA MACHINE LEARNING MODELS

(71) Applicant: AUTODESK, INC., San Francisco, CA (US)

(72) Inventors: George William FITZMAURICE, Toronto (CA); Jo Karel VERMEULEN, East York (CA); Justin Frank MATEJKA, Newmarket (CA)

(21) Appl. No.: 18/749,265

(22) Filed: Jun. 20, 2024

Related U.S. Application Data
(60) Provisional application No. 63/519,799, filed on Aug. 15, 2023.

(51) Int. Cl. G06F 30/27

(52) U.S. Cl. CPC G06F 30/27

(57) ABSTRACT

In various embodiments, a computer-implemented method for performing an analysis of a sketch to identify one or more objects for a generative design, the method comprising receiving the sketch via a user interference, executing a first trained machine learning (ML) model that generates an identification of a first object included in the sketch based on one or more contextual features that are associated with the first object and also are included in the sketch, transmitting the identification to a second machine learning model, and executing a second trained ML model that generates a first design object based on the identification.

### CROSS-REFERENCE TO RELATED APPLICATIONS

This application claims priority benefit of the United States Provisional Patent Application titled, “CONTEXTUAL SEARCH USING PROMPT SCALE, ORIENTATION, AND SURROUNDING OBJECTS,” filed on Aug. 15, 2023, and having Ser. No. 63/519,799. The subject matter of this related application is hereby incorporated herein by reference.

### BACKGROUND

### Field of the Various Embodiments

The various embodiments relate generally to computer-aided design and artificial intelligence and, more specifically, to sketch analysis for generative design via machine learning models.

### Description of the Related Art

Design exploration for three-dimensional (3D) objects generally refers to a phase of a design process during which a designer experiments with using various 3D objects within an overall 3D design. During this design phase, the designer usually generates and modifies numerous 3D objects to determine which 3D objects or versions of 3D objects work best within the overall 3D design. As is well-understood, manually generating and modifying even a relatively simple 3D object is typically very labor-intensive and time-consuming. Because the time allocated for generating a 3D design is usually limited, a designer normally can experiment with only a limited number of 3D objects for a given 3D design. Consequently, the designer inevitably uses sub-optimized 3D objects within the final 3D design and/or fails to use certain 3D objects altogether within the final 3D design, thereby reducing the overall quality of the final 3D design. Accordingly, various conventional computer-aided design (CAD) applications have been developed that attempt to automate more fully how 3D objects are generated during the design exploration process.

One approach to automating how CAD applications generate 3D objects within a 3D design involves implementing an artificial intelligence (AI) model, such as a generative machine learning (ML) model, to automatically synthesize 3D objects in response to prompts provided by the user. A prompt provided to the AI model can be in the form of a query or design problem statement that specifies one or more design characteristics that guide how the AI model should generate the 3D object. The AI model generates a response to the prompt, such as a natural language text response (displayed in a prompt space) and/or a 3D object (displayed in a design space) that satisfies the query or design characteristics specified in the prompt. In addition to text prompts, the user can also enter sketches (in the form of sketch files) in the prompt space for submission to the AI model. The sketches can illustrate particular types of objects that the user wishes to receive corresponding 3D objects from the AI model. For example, if the user wishes to receive 3D objects for a ceiling fan (referred to as the “intended object”), the user can submit a sketch of a room with a fan on the ceiling of the room.

One drawback of the above approach is that conventional AI models incorporated into conventional CAD applications are not able to reliably generate design objects that are responsive to the different intents of a user. In particular, conventional AI models are not able to assess and analyze contextual features included in the sketches submitted by the user and, thus, cannot accurately and consistently identify the intended objects drawn in the sketches. To illustrate, referring back to the above example of the sketch of a room with a fan on the ceiling of the room, a conventional AI model may generate and return 3D objects for various types of objects that are visually similar to a fan, such as a window fan, blender blade, or boat propeller, but may not generate and return a 3D object for the actual intended object (a ceiling fan) because the conventional AI model is not able to assess and analyze the contextual features included in the room sketch, such as the downward orientation and high placement of the fan of the ceiling. Because the AI models included in conventional CAD applications are frequently unable to generate and return 3D objects that accurately reflect the design intents of a user, additional sketches and/or text prompts from the user are typically required, which can substantially reduce the efficiency of the overall design process and the overall quality of 3D designs.

As the foregoing illustrates, what is needed in the art are more effective techniques for generating 3D objects for 3D designs.

### SUMMARY

In various embodiments, a computer-implemented method for performing an analysis of a sketch to identify one or more objects for a generative design, the method comprising receiving the sketch via a user interference, executing a first trained machine learning (ML) model that generates an identification of a first object included in the sketch based on one or more contextual features that are associated with the first object and also are included in the sketch, transmitting the identification to a second machine learning model, and executing a second trained ML model that generates a first design object based on the identification.

At least one technical advantage of the disclosed techniques relative to the prior art is that the disclosed techniques provide an analysis of a sketch based on contextual features/characteristics included within the sketch to more accurately infer/identify intended objects within the sketch. In this regard, a sketch-analysis AI model can be trained to analyze the objects and contextual features/characteristics within different sketches, such as the orientation, size/scale, and/or placement/location of different objects illustrated within the sketches. During inferencing, the trained sketch-analysis AI model can then be used to identify one or more intended objects within a given input sketch. The identifications of the one or more intended objects can then be submitted to a downstream generative AI model that is trained to generate and return one or more design objects (such as 3D objects) corresponding to the one or more intended objects identified by and received from the trained sketch-analysis AI model. The one or more design objects can then be incorporated into an overall design (such as an overall 3D design). Accordingly, the disclosed techniques enable more accurate identification of intended objects illustrated in user sketches relative to what can be achieved using prior approaches. In this manner, the disclosed techniques can reduce or eliminate the need for the additional sketches and/or text prompts from the user that are commonly required with prior art approaches. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design exploration application of FIG. 1, according to various embodiments;

FIG. 3 illustrates an exemplar kitchen sketch included in the sketch file of FIG. 2, according to various embodiments;

FIG. 4 illustrates an exemplar room sketch included in the sketch file of FIG. 2, according to various embodiments;

FIG. 5 illustrates an exemplar car sketch included in the sketch file of FIG. 2, according to various embodiments;

FIG. 6 sets forth a flow diagram of method steps for performing a sketch analysis, according to various embodiments;

FIG. 7 sets forth a flow diagram of method steps for training and retraining a sketch-analysis machine learning model, according to various embodiments; and

FIG. 8 depicts one architecture of a system within which the various embodiments may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

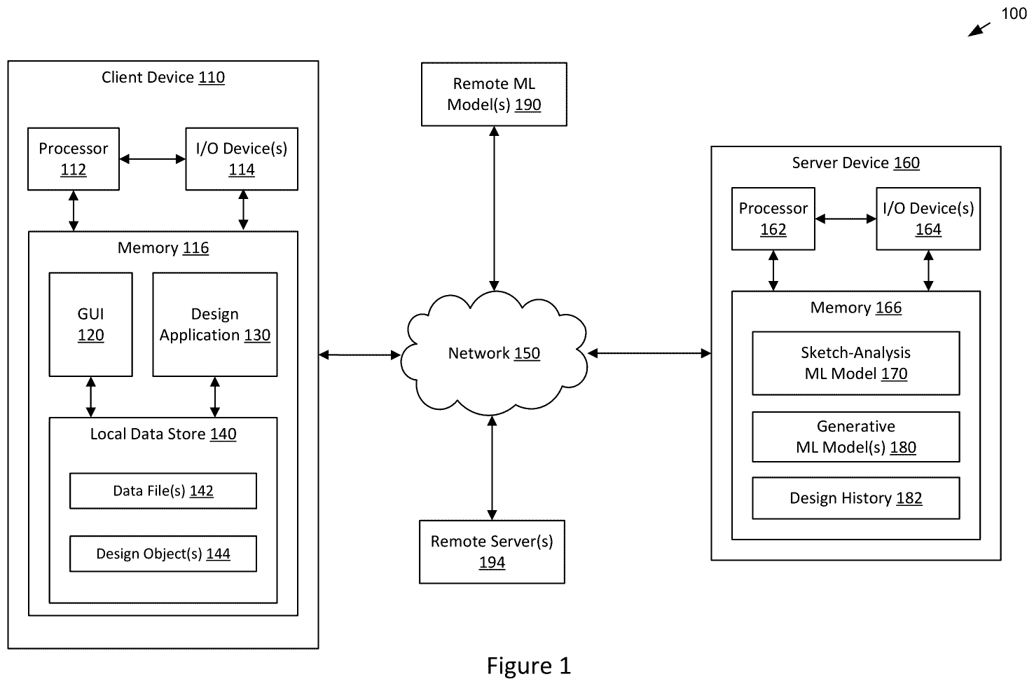

FIG. 1 is a conceptual illustration of a system 100 configured to implement one or more aspects of the various embodiments. As shown, in some embodiments, the system 100 includes, without limitation, a client device 110, a server device 160, one or more remote machine learning (ML) models 190, and one or more remote servers 194.

The client device 110 includes, without limitation, a processor 112, one or more input/output (I/O) devices 114, and a memory 116. The memory 116 includes, without limitation, a graphical user interface (GUI) 120, a design exploration application 130, and a local data store 140. The local data store 140 includes, without limitation, one or more data files 142 and/or one or more design objects 144. The server device 160 includes, without limitation, a processor 162, one or more I/O devices 164, and a memory 166. The memory 166 includes, without limitation, a trained sketch-analysis ML model 170, one or more trained generative ML models 180, and design history 182. In some other embodiments, the system 100 can include any number and/or types of other client devices, server devices, remote ML models, databases, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e., one or more other compute instances and/or a display device) into a user device. Some examples of user devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design exploration application 130 to generate one or more two-dimensional (2D) or 3D designs, such as 2D designs comprising 2D objects and/or 3D designs for 3D objects. In some embodiments, the design exploration application 130 causes one or more generative ML models 180, 190 to synthesize designs based on any number of goals and constraints. The design exploration application 130 then presents the designs as one or more design objects 144 to a user in the context of a design space. In some embodiments, the design objects 144 comprise 2D objects, such as sub-portions of a 2D design, each sub-portion comprising 2D geometries. For example, a 2D design can comprise a building layout and a 2D design object 144 can comprise a particular room of the building layout. Both 2D and 3D designs and design objects 144 can be processed in a similar manner by the embodiments and techniques described herein. In some embodiments, the user can explore and modify the design objects 144 via the GUI 120.

In various embodiments, the processor 112 can be any instruction execution system, apparatus, or device capable of executing instructions. For example, the processor 112 can comprise general-purpose processors (such as a central processing unit), special-purpose processors (such as a graphics processing unit), application-specific processors, field-programmable gate arrays, or other programmable logic device, discrete gate or transistor logic, discrete hardware components, or any combination of different processing units. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, trackball, and so forth. In some embodiments, the I/O devices 114 also includes devices configured to provide output, including, for example, a display device, a speaker, and so forth. For example, an input device can enable a user to control a cursor displayed on an output device for selecting various elements displayed on the output device 114. Additionally or alternatively, the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design exploration application 130, and data (e.g., the data files 142 and/or the design objects stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design exploration application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design exploration application 130 resides in the memory 116 and executes on the processor 112 of the client device 110. The design exploration application 130 interacts with a user via the GUI 120. In various embodiments, the design exploration application 130 operates as a 2D or 3D design application to generate and modify an overall 2D or 3D design that includes one or more 2D or 3D design objects 144. The design exploration application 130 interacts with a user via the GUI 120 to generate the one or more design objects 144 via direct user input (e.g., one or more tools of the design exploration application 130 are used to generate 3D objects, wireframe geometries, meshes, etc.) or via separate devices (e.g., the sketch-analysis ML model 170, the trained ML models 180, the remote ML models 190, separate 3D design applications, etc.).

When generating the one or more design objects 144 via separate devices, the design exploration application 130 generates (based on user inputs) a prompt that includes a sketch that illustrates one or more intended objects that the user wishes to receive one or more design objects generated by the ML models 180, 190. The design exploration application 130 then causes the sketch-analysis ML model 170 and one or more of the generative ML models 180, 190 to operate on the generated prompt to identify the one or more intended objects illustrated in the sketch, and generate a relevant ML response, including one or more design objects 144 corresponding to the one or more identified intended objects. The design exploration application 130 receives the ML response from the one or more ML models 180, 190 and displays the ML response (including the one or more design objects 144) within the GUI 120. The user can select, via the GUI 120, the one or more design objects 144 for modification or use, such as incorporating the one or more design objects 144 into the overall design displayed in the GUI 120.

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design exploration application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the design exploration application 130 organizes GUI elements into one or more container GUI elements (e.g., panels and/or panes).

The local data store 140 is a part of storage in the client device 110 that stores one or more design objects 144 included in an overall design and/or one or more data files 142 associated with the overall design. For example, an overall 3D design for a building can include multiple stored design objects 144, including design objects 144 separately representing doors, windows, fixtures, walls, appliances, and so forth. The design objects 144 include geometries, textures, images, and/or other components that the design exploration application 130 uses to generate an overall 2D or 3D design. In some embodiments, the geometry of a given design object refers to any multi-dimensional model of a physical structure, including CAD models, meshes, and point clouds, as well as building layouts, circuit layouts, piping diagrams, free-body diagrams, and so forth. The local data store 140 can also include data files 142 relating to an overall 3D design (e.g., component files, metadata, etc.). Additionally or alternatively, the local data store 140 includes data files 142 related to generating prompts for transmission to the sketch-analysis ML model 170 and the one or more ML models 180, 190. For example, the local data store 140 can store one or more data files 142 for sketches, geometries (e.g., wireframes, meshes, etc.), images, videos, application states (e.g., camera angles used within a design space, tools selected by a user, etc.), audio recordings, and so forth.

The network 150 can be any technically feasible set of interconnected communication links, including a local area network (LAN), wide area network (WAN), the World Wide Web, or the Internet, among others. The network 150 enables communications between the client device 110 and other devices in network 150 via wired and/or wireless communications protocols, including Bluetooth, Bluetooth low energy (BLE), wireless local area network (WiFi), cellular protocols, satellite networks, and/or near-field communications (NFC).

The server device 160 is configured to communicate with the design exploration application 130 to generate one or more ML responses (such as design objects) in response to one or more prompts. In operation, the server device 160 executes the sketch-analysis ML model 170 to process a prompt (including a sketch) that is received from the design exploration application 130 to identify one or more intended objects within the sketch, then cause the one or more generative ML models 180, 190 to generate one or more design objects 144 corresponding to the one or more identified intended objects. Once the selected ML models 180, 190 generate the one or more design objects 144 that are responsive to the prompt, the server device 160 transmits the generated design objects to the client device 110, where the generated design objects 144 are usable by the design exploration application 130. For example, the design exploration application 130 can display the generated design objects 144 in the GUI 120 for exploration, manipulation, and/or modification by the user.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, the I/O devices 164 also includes devices configured to provide output, including, for example, a display device, a speaker, and so forth. Additionally or alternatively, the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the sketch-analysis ML model 170 and the one or more trained ML models 180, and data (e.g., design history 182) for processing by the processor 162. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the sketch-analysis ML model 170 and/or the one or more ML models 180 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally or alternatively, the sketch-analysis ML model 170 could be executed on the client device 110 and can communicate with the trained ML models 180 operating at the server device 160.

In various embodiments, the sketch-analysis ML model 170 receives a prompt (including a sketch) from the design exploration application 130, identifies one or more intended objects within the sketch, and generates object information associated with each identified intended object, including Identification information and descriptive information. The sketch-analysis ML model 170 then outputs the object information for each intended object to an appropriate ML model 180, 190. In some embodiments, the user enters into the prompt space a text input specifying a particular type of design object that is desired, such as 2D geometry, 3D geometry, or an image. In these embodiments, the one or more of the generative ML models 180, 190 are trained to respond with specific types of outputs in response to a received text description (the object information). For example, a generative ML model can be trained to generate design objects comprising 2D geometry or 3D geometry in response to a received text description (the object information). As another example, a generative ML model can be trained to generate design objects comprising images in response to a received text description (the object information). In such instances, the sketch-analysis ML model 170 submits the object information to the appropriate ML model 180, 190 based on the desired type of design objects.

In alternative embodiments, the trained sketch-analysis ML model 170 and one or more generative ML models 180, 190 comprise a single integrated/combined ML model that is trained to receive sketches illustrating intended objects, identify the intended objects in the sketches, and output design objects 270 corresponding to the intended objects. For example, in these embodiments, the functions of the trained sketch-analysis ML model 170 and a generative ML model 180 on the server device 160 can be combined into a single integrated ML model that is trained to perform the functions of both the trained sketch-analysis ML model 170 and the generative ML model 180.

In some embodiments, the sketch-analysis ML model 170 can be retrained using evaluations provided by the user. In these embodiments, the user can submit a first prompt including a sketch for a particular intended object via the design exploration application 130, which submits the first prompt to the sketch-analysis ML model 170, which in turn identifies an object within the sketch and inputs object information describing the identified object to a selected ML model 180, 190, which generates a design object 144 corresponding to the identified object. The generated design object 144 is then returned to the design exploration application 130, which displays the generated design object 144 in the GUI 120. The user can then enter a second prompt that includes an evaluation (feedback) of the response received for the first prompt (i.e., the generated design object 144), such as “the received object is correct,” or “the received object is incorrect.” The server device 160 can then store the first prompt (including the sketch), the object information describing the identified object, and the second prompt (including the feedback) as additional training data for retraining the sketch-analysis ML model 170 at a later time. The server device 160 can store the additional training data in the design history 182, and then use the design history 182 to retrain the sketch-analysis ML model 170 for improving the accuracy of the sketch-analysis ML model 170 in identifying intended objects within sketches (increase the probability that the sketch-analysis ML model 170 infers/identifies the correct objects within the sketches).

The ML models 180 include one or more generative ML models that have been trained on a relatively large amount of existing data and optionally any number of results (e . . . , design objects 144 and evaluations provided by the user) to perform any number and/or types of prediction tasks based on patterns detected in the existing data.

In various embodiments, the remote ML models 190 are additional trained ML models that communicate with the server device 160 to receive prompts (object information) via the sketch-analysis ML model 170. For example, in some embodiments, the one or more trained ML models 180 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth. In various embodiments, the trained ML models 180 can be trained to generate design objects to response to text prompts (object information).

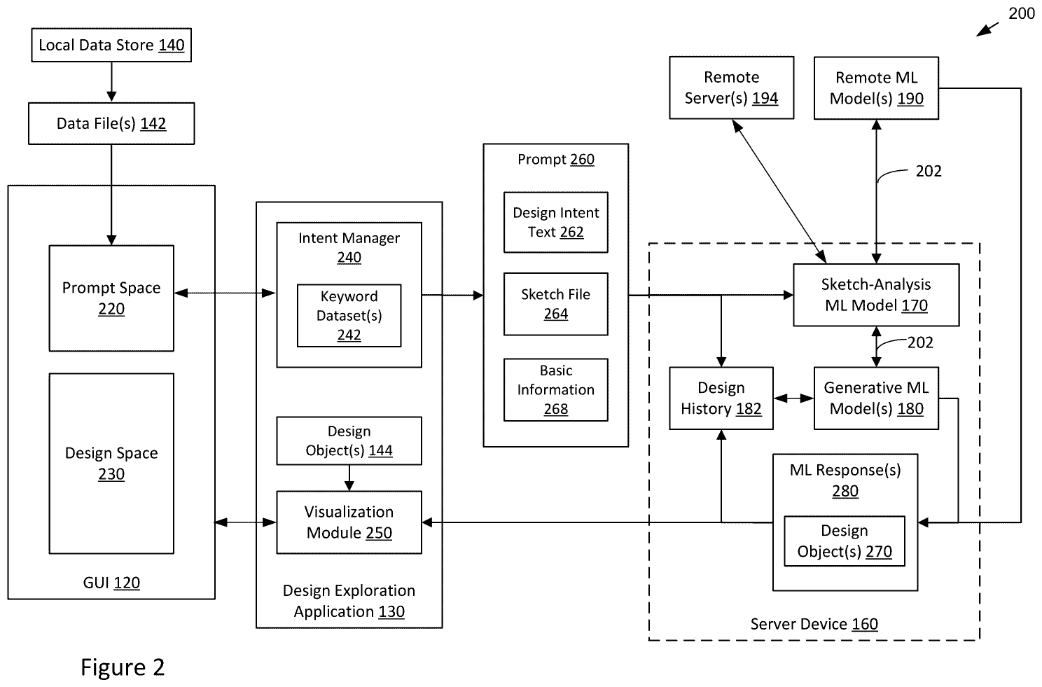

FIG. 2 is a more detailed illustration of the design exploration application 130 of FIG. 1, according to various embodiments. As shown, in some embodiments, the system 200 includes, without limitation, the design exploration application 130, the GUI 120, the local data store 140, the one or more data files 142, the one or more remote servers 194, the server device 160, the remote ML models 190, a prompt 260, and object information 202.

The GUI 120 includes, without limitation, a prompt space 220 and a design space 230. The design exploration application 130 includes, without limitation, an intent manager 240 including one or more keyword datasets 242, the one or more design objects 144, and a visualization module 250. The server device 160 includes, without limitation, the sketch-analysis ML model 170, object information 202 generated by the sketch-analysis ML model 170, the one or more ML models 180, the design history 182, and one or more ML responses 280 (including one or more design objects 270) that are generated by the server device 160 in response to received prompts 260. The prompt 260 includes, without limitation, a design intent text 262, a sketch file 264, and basic information 268.

For explanatory purposes only, the functionality of the design exploration application 130 is described herein in the context of exemplar interactive and linear workflows used to generate a design object 270 in accordance with user-based design-related intentions expressed during the workflow. The generated design object 270 includes, without limitation, one or more images, wireframe models, 2D or 3D geometries, and/or meshes for use in a 2D or 3D design, as well and any amount (including none) and/or types of associated metadata. As persons skilled in the art will recognize, the techniques described herein are illustrative rather than restrictive and can be altered and applied in other contexts without departing from the broader spirit and scope of the inventive concepts described herein. For example, the techniques described herein can be modified and applied to generate any number of generated design objects 270 associated with any target design object in a linear fashion, a nonlinear fashion, an iterative fashion, a non-iterative fashion, a recursive fashion, a non-recursive fashion, or any combination thereof during an overall process for generating and evaluating designs for that target design object. A target design object can include any number (including one) and/or types of target design objects and/or target design object components.

In operation, the visualization module 250 of the design exploration application 130 generates and renders the GUI 120, which includes the prompt space 220 and the design space 230. In general, the design space 230 displays the overall design having one or more design objects that can include one or more design objects that have been automatically generated or modified by the AI model. The prompt space 220 provides an input area for interacting with the AI model. The prompt space receives the user inputs that are used for generating prompts to the AI model. The prompt space also displays a prompt history of all prompt interactions with the AI model, including the user text inputs for generating the various prompts and the text responses from the AI model to the prompts.

A user can provide at least a portion of the content for the prompt 260 via the prompt space 220 (e.g., by entering text inputs and sketch files 264 into the prompt space 220). The prompt space 220 is a panel in which a user can input content that is used to generate the prompts 260. For example, a user can input a regular sentence (“I want a 3D object for the object X shown in the sketch,” or “I want an image for the object X shown in the sketch”) within an input area within the prompt space 220. In various embodiments, the intent manager 240 determines the intent of inputs provided by the user. For example, the intent manager 240 can comprise a natural language (NL) processor that parses text input provided by the user. Additionally or alternatively, the intent manager 240 can process audio data to identify words included in audio data and parse the identified words. In various embodiments, the intent manager 240 identifies one or more keywords in textual data. In some embodiments, the intent manager 240 includes one or more keyword datasets 242 that the intent manager 240 references when identifying the one or more keywords included in textual data. In other embodiments, the sketch-analysis ML model 170 can be trained to respond and execute without a user text input. In these embodiments, the sketch-analysis ML model 170 is trained to analyze the sketch and determine which portions of the sketch needs to be resolved and complete these portions with inference.

The design exploration application 130 receives textual and/or non-textual data to include in the prompt 260 via the input area of the prompt space 220. When providing non-textual data, the user can retrieve stored data, such as one or more sketch files 264 that are stored as data files 142 in the local data store 140. Each sketch file 264 can store a user sketch illustrating one or more intended objects, the sketch including one or more contextual features for each intended object that indicate the identity of the intended object. The one or more contextual features for an intended object can include an orientation, size/scale, and/or placement/location of the intended object within the sketch. For example, the one or more contextual features for an intended object can include an orientation of the intended object relative to an orientation of another object within the sketch. For example, the one or more contextual features for an intended object can include a size/scale of the intended object relative to a size/scale of another object within the sketch. For example, the one or more contextual features for an intended object can include a placement/location of the intended object relative to a placement/location of another object within the sketch.

A sketch can comprise a user hand-drawn “pen and paper” illustration/drawing that is scanned or otherwise digitally captured into a sketch file 264. In other embodiments, a sketch can comprise a user illustration/drawing produced using a computer based “pen-type” input device that the user manipulates to draw the sketch via a software application (such as a drawing or sketching software application) that digitally captures and stores the sketch as a sketch file 264. In further embodiments, a sketch can comprise a simple computer-based diagram that is produced by the user using a software application (such as a design software application) via software drawing/diagram tools which is digitally captured and stored as a sketch file 264.

The design exploration application 130 processes the content entered into the prompt space 220 to generate the prompt 260 which can include the design intent text 262, sketch file 264, and basic information 268. The prompt 260 generally specifies the design intent of the user. In various embodiments, the intent manager 240 receives content/data and builds the prompt 260 based on the received content/data. For example, a user can initially input design intent text 262 that refers to a sketch (such as “I want a 3D design object for the object X shown in the sketch”). The design exploration application 130 then receives a sketch (a sketch file 264). Upon receiving the sketch, the design exploration application 130 can then generate the prompt 260 to include both the design intent text 262 and the sketch file 264. In some embodiments, the design exploration application 130 generates design intent text from a different type of data input. For example, the intent manager 240 can perform NL processing to identify words included in an audio recording. In such instances, the design exploration application 130 generates design intent text 262 that includes the identified words.

In some embodiments, the intent manager 240 also determines basic information 268 associated with the sketch file 264 and includes the basic information 268 in the prompt 260. For example, the intent manager 240 can process the sketch file 264 to determine if any drawn text is included within the sketch (such as the sketch labels “kitchen” or “car”) and convert the drawn text into computer-based ASCII text (e.g., using optical character recognition) to include in the basic information 268. As another example, the intent manager 240 can process metadata of the sketch file 264 to extract other types of basic information 268. For example, the intent manager 240 can extract the filename of the sketch file (such as “kitchensketch” or “carsketch”) and include the filename in the basic information 268. The basic information 268 can be included in the prompt 260 to provide additional information to assist the sketch-analysis ML model 170 to more accurately identify one or more intended objects within the sketch (increase the probability that the sketch-analysis ML model 170 infers/identifies the correct objects within the sketches).

After generating the prompt 260, the design exploration application 130 then transmits the prompt 260 to the server device 160. The sketch-analysis ML model 170 receives the prompt 260, identifies at least one intended object within the sketch included in the sketch file 264, and generates object information 202 for each identified intended object. The sketch-analysis ML model 170 identifies at least one intended object within the sketch based on the contents of the prompt 260, such as the design intent text 262, sketch file 264, and basic information 268. The sketch file 264 includes a sketch illustrating one or more intended objects and one or more contextual features for each intended object (such as a relative orientation, relative size/scale, and/or relative placement/location of the intended object within the sketch). The sketch-analysis ML model 170 identifies the at least one intended object within the sketch by analyzing the illustrations of at least one intended object and the contextual features of the at least one intended object within the sketch. As discussed below, the sketch-analysis ML model 170 is trained to analyze objects and contextual features of objects within sketches to identify the specific types of objects within the sketches.

The sketch-analysis ML model 170 then generates object information 202 associated with each identified object within the sketch. In some embodiments, the object information for an identified object includes identification information and descriptive information. The identification information uniquely identifies a specific type of object, such as a “ceiling fan,” “window fan,” “blender blade,” “automobile radio antenna,” and the like. The descriptive information includes additional description of the object specified by the identification information, such as typical physical dimensions (width, height, depth), typical geometric shapes, typical weights or mass, typical materials, typical manufacturing processes used, typical colors, and the like. For example, the sketch-analysis ML model 170 can perform an Internet search for the descriptive information based on the identification information and retrieve the descriptive information from one or more remote servers 194. As another example, the descriptive information can be embedded in the trained sketch-analysis ML model 170 itself.

The sketch-analysis ML model 170 then selects one or more trained ML models 180 and/or remote ML models 190 that have been trained to generate the types of design objects requested in the prompt 260 (such as 2D objects, 3D objects, or images). The sketch-analysis ML model 170 then executes the selected ML models 180, 190 by inputting the object information 202 into the selected ML models 180, 190. The selected ML models 180, 190 respond to the object information 202 by generating an ML response 280 that include at least one design object 270 corresponding to the at least one intended object specified in the object information 202. In some embodiments, the server device 160 includes the generated design object 270 in the design history 182. In such instances, the generated design object 270 is a portion of the design history 182 that can be used as additional training data to retrain one or more trained ML models 180 (egg., further training the selected ML model, training other ML models, etc.).

The visualization module 250 receives the one or more generated design objects 270 and displays the one or more generated design objects 270 in the design space 230. In various embodiments, the design space 230 is a virtual workspace that includes one or more renderings of design objects (e.g., geometries of the current design objects 144 and/or newly generated design objects 270) that form an overall 3D design. The design exploration application 130 provides various tools to enable the user to interact with the GUI 120 to modify and/or implement the one or more generated design objects 270 within the overall 3D design. In addition, the user may submit a follow-up prompt providing and evaluation (feedback) indicating whether received the design object 270 correctly corresponds to an intended object illustrated within the user sketch, such as “the received object is correct,” or “the received object is incorrect.” The server device 160 can then store to the design history 182 the initial prompt (including the sketch), the object information 202 generated for the initial prompt, the one or more generated design objects 270, and the feedback prompt as additional training data for retraining the sketch-analysis ML model 170 for improving the accuracy of the sketch-analysis ML model 170 in identifying intended objects within sketches.

### Analysis of Sketches for Generative Design

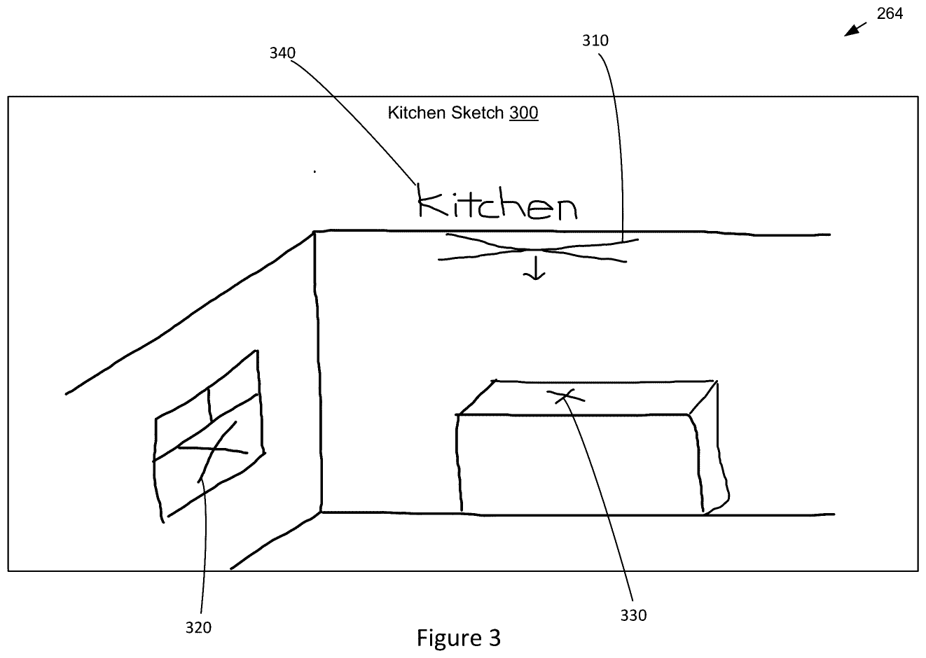

In some embodiments, a sketch illustrates an intended object via a drawn shape comprising a non-text drawn structure or figure that visually/graphically represents the intended object. In these embodiments, the drawn shape representing the intended object has one or more contextual features that indicate the identity of the intended object, including a relative orientation, relative size/scale, and/or relative placement/location of the drawn shape within the sketch. The sketch-analysis ML model 170 is trained to analyze the illustrations of the drawn shape and the one or more contextual features of the drawn shape in the sketch to identify the intended object represented by the drawn shape. FIG. 3 shows an example of a sketch illustrating an intended object via a drawn shape.

FIG. 3 illustrates an exemplar kitchen sketch 300 included in the sketch file 264 of FIG. 2, according to various embodiments. As shown, the kitchen sketch 300 illustrates a first intended object 310, a second intended object 320, a third intended object 330, and a drawn text 340. The first intended object 310 comprises a ceiling fan located on the ceiling of the kitchen and is represented by the illustration of a drawn shape comprising a large “X.” The second intended object 320 comprises a window fan located in a wall of the kitchen and is represented by the illustration of a drawn shape comprising a medium “X.” The third intended object 320 comprises a blender blade located on top of a kitchen table and is represented by the illustration of a drawn shape comprising a small “X.” In the embodiments described below, the kitchen sketch 300 includes multiple intended objects 310, 320, 330. In other embodiments, the kitchen sketch 300 can include only one of the intended objects 310, 320, 330.

The prompt space 220 of the design exploration application 130 can receive the sketch file 264 containing the kitchen sketch 300 along with text input (such as “I want 3D objects for the objects X shown in the sketch”) and generate a prompt 260 based on the received inputs. The design exploration application 130 can extract the drawn text 340 “kitchen” from the sketch 300 and convert the drawn text into computer-based ASCII text (e.g., using optical character recognition) to include the text as basic information 268 in the generated prompt 260. The prompt 260 including the kitchen sketch 300 and the basic information 268 is then transmitted to the sketch-analysis ML model 170 which identifies the intended objects 310, 320, 330 within the kitchen sketch 300 based on the basic information 268 and the illustrations of the objects 310, 320, 330 and the one or more contextual features included in the kitchen sketch 300.

The first intended object 310 comprising the ceiling fan and represented by the drawn shape of a large “X” has one or more associated contextual features. In particular, the first intended object 310 has an associated orientation feature that is illustrated/indicated by the downward and horizontal orientation of the large “X,” the orientation parallel to the ceiling and ground, and the downward pointing orientation arrow adjacent to the large “X”. The first intended object 310 also has an associated placement/location feature that is illustrated/indicated by the relative placement of the large “X” on the ceiling of the kitchen and further illustrated/indicated by the relative placement of the large “X” above the second intended object 320 (window fan), the kitchen table, and the third intended object 330 (blender blade). The first intended object 310 also has an associated size/scale that is illustrated/indicated by the larger size of the large “X” relative to both the size of the medium “X” representing the second intended object 320 (window fan), and the size of the small “X” representing the third intended object 330 (blender blade). The sketch-analysis ML model 170 is trained to analyze the orientation, relative size/scale, and/or relative placement/location of the drawn shape large “X” within the kitchen sketch 300 to specifically identify the first intended object 310 as a ceiling fan.

The second intended object 320 comprising the window fan and represented by the drawn shape of a medium “X” has one or more associated contextual features. In particular, the second intended object 320 has an associated orientation feature that is illustrated/indicated by the forward and vertical orientation of the medium “X” in a window along a wall of the kitchen and the orientation parallel to the wall of the kitchen. The second intended object 320 also has an associated placement/location feature that is illustrated/indicated by the relative placement of the medium “X” in a window along the wall of the kitchen and further illustrated/indicated by the relative placement of the medium “X” below the first intended object 310 (ceiling fan) and to the side of the kitchen table and the third intended object 330 (blender blade). The second intended object 320 also has an associated size/scale that is illustrated/indicated by the smaller size of the medium “X” relative to the size of the large “X” representing the first intended object 320 (ceiling fan), and the larger size of the medium “X” relative to the size of the small “X” representing the third intended object 330 (blender blade). The sketch-analysis ML model 170 is trained to analyze the orientation, relative size/scale, and/or relative placement/location of the drawn shape medium “X” within the kitchen sketch 300 to specifically identify the second intended object 320 as a window fan.

The third intended object 330 comprising the blender blade and represented by the drawn shape of a small “X” has one or more associated contextual features. In particular, the third intended object 330 has an associated orientation feature that is illustrated/indicated by the upward and horizontal orientation of the small “X” on the kitchen table and the orientation parallel to the top of the kitchen table. The third intended object 330 also has an associated placement/location feature that is illustrated/indicated by the relative placement of the small “X” on the kitchen table and further illustrated/indicated by the relative placement of the small “X” below the first intended object 310 (ceiling fan) and to the side of the kitchen wall and the second intended object 320 (window fan). The third intended object 330 also has an associated size/scale that is illustrated/indicated by the smaller size of the small “X” relative to both the size of the large “X” representing the first intended object 320 (ceiling fan) and the size of the medium “X” representing the second intended object 320 (window fan). The sketch-analysis ML model 170 is trained to analyze the orientation, relative size/scale, and/or relative placement/location of the drawn shape small “X” within the kitchen sketch 300 to specifically identify the third intended object 330 as a blender blade.

After identifying the intended objects 310, 320, 330, the sketch-analysis ML model 170 then generates object information 202 associated with each identified intended object 310, 320, 330. The object information 202 for an identified object can include identification information and descriptive information. The identification information uniquely identifies a specific type of object, such as a “ceiling fan,” “window fan,” or “blender blade.” The descriptive information includes additional description of the object specified in the identification information. The object information 202 is then input to one or more generative ML models 180, 190 that generate an ML response 280 containing one or more design objects 270 for each intended object 310, 320, 330. The design exploration application 130 receives the ML response 280 and displays the design objects 270 within the design space 230.

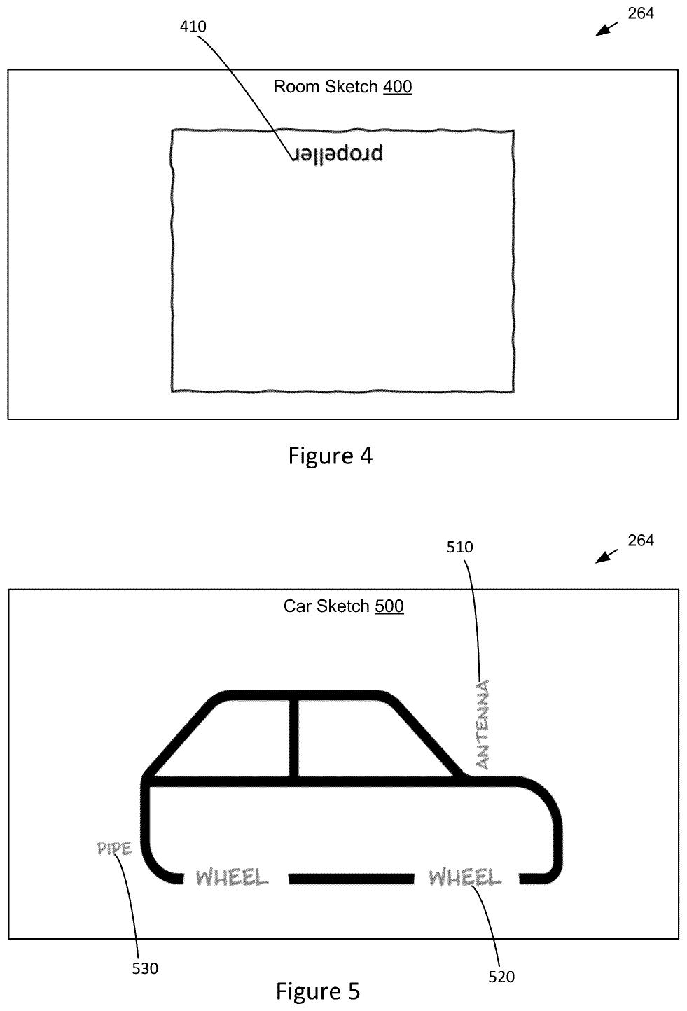

In some embodiments, a sketch illustrates an intended object via drawn text that represents the intended object. In these embodiments, the drawn text representing the intended object has one or more contextual features that indicate the identity of the intended object, including a relative orientation, relative size/scale, and/or relative placement/location of the drawn text within the sketch. The sketch-analysis ML model 170 is trained to analyze the illustrations of the drawn text and the one or more contextual features of the drawn text in the sketch to identify the intended object represented by the drawn text. FIGS. 4-5 show examples of sketches illustrating an intended object via a drawn text.

FIG. 4 illustrates an exemplar room sketch 400 included in the sketch file 264 of FIG. 2, according to various embodiments. FIG. 4 illustrates how the intended object “ceiling fan” that is represented by a drawn shape in FIG. 3 can also be represented by a drawn text in FIG. 4. As shown, the room sketch 400 illustrates an intended object 410 comprising a ceiling fan represented by the illustration of a drawn text “propeller.” The prompt space 220 of the design exploration application 130 can receive the sketch file 264 containing the room sketch 400 along with text input (such as “I want 3D objects for the ‘propeller’ shown in the sketch”) and generate a prompt 260 based on the received inputs, which is transmitted to the sketch-analysis ML model 170. The sketch-analysis ML model 170 identifies the intended object 410 within the room sketch 400 based on the illustrations of the intended object 410 and the one or more contextual features included in the room sketch 400.

The intended object 410 comprising the ceiling fan and represented by the drawn text “propeller” has one or more associated contextual features. In particular, the intended object 410 has an associated orientation feature that is illustrated/indicated by the downward and horizontal orientation of the drawn text “propeller,” and the orientation parallel to the ceiling and ground. The intended object 410 also has an associated placement/location feature that is illustrated/indicated by the relative placement of the drawn text “propeller” on the ceiling of the room. The intended object 410 also has an associated size/scale that is illustrated/indicated by the size of the drawn text “propeller” relative to the size of the room. The sketch-analysis ML model 170 is trained to analyze the orientation, relative size/scale, and/or relative placement/location of the drawn text “propeller” within the room sketch 400 to specifically identify the intended object 410 as a ceiling fan.

After identifying the intended object 410, the sketch-analysis ML model 170 then generates object information 202 associated with the identified intended object 410, which is then input to one or more generative ML models 180, 190 that generate an ML response 280 containing one or more design objects 270 for the intended object 410. The design exploration application 130 receives the ML response 280 and displays the design objects 270 within the design space 230.

FIG. 5 illustrates an exemplar car sketch 500 included in the sketch file 264 of FIG. 2, according to various embodiments. As shown, the car sketch 500 illustrates a first intended object 510, a second intended object 520, and a third intended object 530. The first intended object 510 comprises an automobile radio antenna represented by the illustration of a drawn text “antenna.” The second intended object 520 comprises an automobile rim and tire represented by the illustration of a drawn text “wheel.” The third intended object 520 comprises an automobile exhaust pipe represented by the illustration of a drawn text “pipe.” In the embodiments described below, the car sketch 500 includes multiple intended objects 510, 520, 530. In other embodiments, the car sketch 500 can include only one of the intended objects 510, 520, 530.

The prompt space 220 of the design exploration application 130 can receive the sketch file 264 containing the car sketch 500 along with text input (such as “I want 3D objects for the ‘antenna,’ ‘wheel,’ and ‘pipe’ shown in the sketch”) and generate a prompt 260 based on the received inputs, which is transmitted to the sketch-analysis ML model 170. The sketch-analysis ML model 170 identifies the intended objects 510, 520, 530 within the car sketch 500 based on one or more contextual features included in the car sketch 500.

The first intended object 510 comprising the automobile radio antenna and represented by the drawn text “antenna” has one or more associated contextual features. In particular, the first intended object 510 has an associated orientation feature that is illustrated/indicated by the vertical orientation of the drawn text “antenna,” and the orientation perpendicular to the ground. The first intended object 510 also has an associated placement/location feature that is illustrated/indicated by the relative placement of the drawn text “antenna” on the hood of the car above the drawn text “wheel” and in front of the drawn text “pipe.” The first intended object 510 also has an associated size/scale that is illustrated/indicated by the smaller size of the drawn text “antenna” relative to the size of the car and the size of the drawn text “wheel,” and the larger size of the drawn text “antenna” relative to the size of the drawn text “pipe.” The sketch-analysis ML model 170 is trained to analyze the orientation, relative size/scale, and/or relative placement/location of the drawn text “antenna” within the car sketch 500 to specifically identify the first intended object 510 as an automobile radio antenna.

The second intended object 520 comprising the automobile rim and tire and represented by the drawn text “wheel” has one or more associated contextual features. In particular, the second intended object 520 has an associated orientation feature that is illustrated/indicated by the orientation of the drawn text “wheel” that is parallel to the side of the car. The second intended object 520 also has an associated placement/location feature that is illustrated/indicated by the relative placement of the drawn text “wheel” on the bottom of the car below the drawn text “antenna” and below the drawn text “pipe.” The second intended object 520 also has an associated size/scale that is illustrated/indicated by the larger size of the drawn text “wheel” relative to both the size of the drawn text “antenna” and the size of the drawn text “pipe.” The sketch-analysis ML model 170 is trained to analyze the orientation, relative size/scale, and/or relative placement/location of the drawn text “wheel” within the car sketch 500 to specifically identify the second intended object 520 as an automobile rim and tire.

The third intended object 530 comprising the automobile exhaust pipe and represented by the drawn text “pipe” has one or more associated contextual features. In particular, the third intended object 530 has an associated orientation feature that is illustrated/indicated by the orientation of the drawn text “pipe” pointing towards the rear of the car. The third intended object 530 also has an associated placement/location feature that is illustrated/indicated by the relative placement of the drawn text “pipe” on the rear of the car behind both the drawn text “antenna” and the drawn text “wheel.” The third intended object 530 also has an associated size/scale that is illustrated/indicated by the smaller size of the drawn text “pipe” relative to both the size of the drawn text “antenna” and the drawn text “wheel.” The sketch-analysis ML model 170 is trained to analyze the orientation, relative size/scale, and/or relative placement/location of the drawn text “pipe” within the car sketch 500 to specifically identify the third intended object 530 as an automobile exhaust pipe.

After identifying the intended objects 510, 520, 530, the sketch-analysis ML model 170 then generates object information 202 associated with each identified intended object 510, 520, 530, which is then input to one or more generative ML models 180, 190 that generate an ML response 280 containing design objects 270 for the intended objects 510, 520, 530. The design exploration application 130 receives the ML response 280 and displays the design objects 270 within the design space 230.

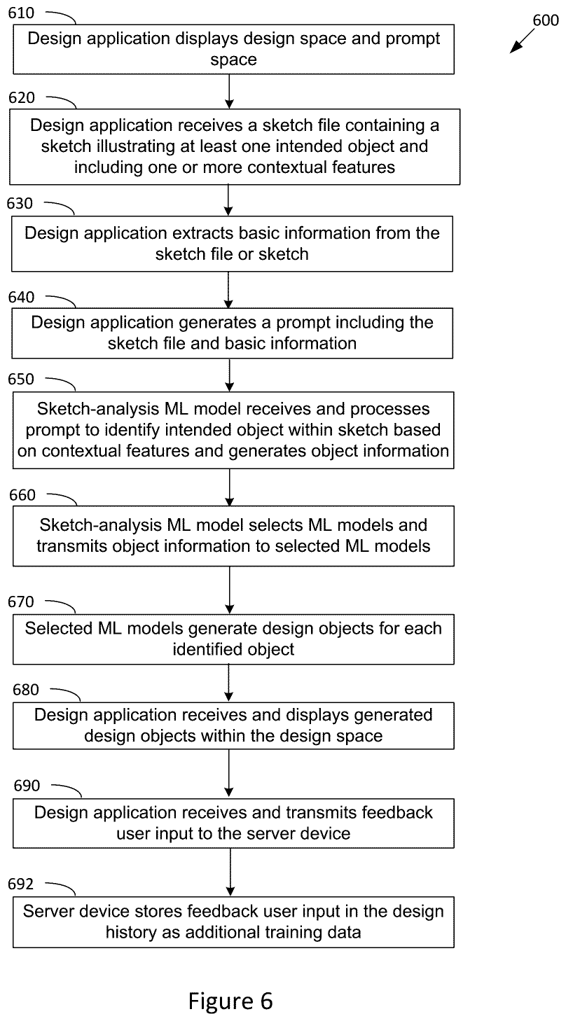

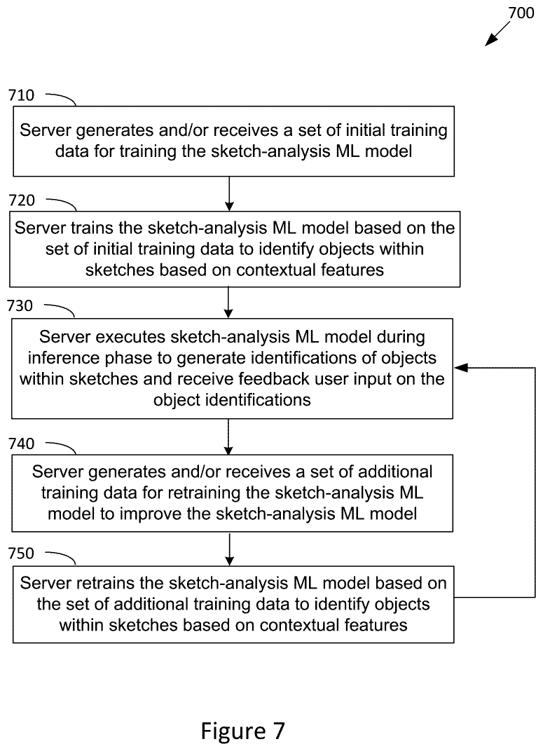

FIG. 6 sets forth a flow diagram of method steps for performing a sketch analysis, according to various embodiments. Although the method steps are described with reference to the systems of FIGS. 1-5, persons skilled in the art will understand that any system configured to implement the method steps, in any order, falls within the scope of the embodiments. In some embodiments, the method 600 is executed in conjunction with a training method 700 described in relation to FIG. 7 which trains and retrains the sketch-analysis ML model 170 for identifying one or more intended objects within a sketch.

As shown, the method 600 begins at step 610, where the design exploration application 130 displays a GUI 120 comprising a design space 230 and a prompt space 220. The design space 230 displays zero or more design objects 144. The design exploration application 130 then receives (at step 620) user input via the prompt space 220, the user input including a sketch file 264 containing a sketch. The sketch illustrates at least one intended object and includes one or more contextual features for the at least one intended object that indicate the identity of the at least one intended object. Optionally, the user input can also include text input, such as “I want a 3D object for the object X shown in the sketch.” The design exploration application 130 then extracts (at step 630) basic information 268 from metadata of the sketch file 264 and/or the sketch, such as the filename of the sketch file or drawn text included in the sketch. The design exploration application 130 then generates (at step 640) a prompt 260 based on the user input(s) and transmits the prompt 260 to the trained sketch-analysis ML model 170. The prompt 260 can include design intent text 262, the sketch file 264, and/or the basic information 268.

The trained sketch-analysis ML model 170 receives and processes the prompt 260 (at step 650) to infer/identify the at least one intended object within the received sketch based on the illustrations of the at least one intended object and the one or more contextual features for the at least one intended object. The trained sketch-analysis ML model 170 also generates object information 202 associated with each identified object within the sketch. In some embodiments, the object information 202 for an identified object includes identification information that indicates the specific type of object and descriptive information that provides additional description of the identified object. For example, the descriptive information can be embedded in the trained sketch-analysis ML model 170 and/or retrieved from one or more remote servers 194. The trained sketch-analysis ML model 170 then selects (at 660) one or more generative ML models 180, 190 for processing the object information 202 and transmits the object information 202 to the selected ML models 180, 190.

The selected ML models 180, 190 receives (at 670) the object information 202 as input and outputs/generates one or more design objects 270 based on the object information 202. In particular, the selected ML models 180, 190 outputs/generates one or more design objects 270 for each identified object specified in the object information 202. For example, the design objects can comprise 2D objects, 3D objects, or images. The selected ML models 180, 190 also transmit an ML response 280 comprising the one or more generated design objects 270 to the design exploration application 130. In other embodiments, the trained sketch-analysis ML model 170 and one or more generative ML models 180, 190 comprise a single combined ML model that is trained to receive sketches illustrating intended objects, identify the intended objects in the sketches, and output design objects 270 corresponding to the intended objects. For example, in these embodiments, the functions of the trained sketch-analysis ML model 170 and a generative ML model 180 on the server device 160 can be combined into a single ML model that is trained to perform the functions of both the trained sketch-analysis ML model 170 and the generative ML model 180.

The design exploration application 130 receives (at 680) the ML response 280 and displays the one or more design objects 270 within the design space 230. The design exploration application 130 then receives (at step 690) another user input via the prompt space 220, the another user input comprising feedback indicating whether the displayed design objects 270 correctly correspond to the intended objects illustrated in the sketch. The design exploration application 130 transmits a second prompt 260 that includes the feedback user input to the server device 160. The server device 160 receives (at step 692) the second prompt 260 and stores to the design history 182 the initial prompt (including the sketch file 264), the object information 202 describing the identified object, the one or more generated design objects 270, and/or the second prompt (including the feedback user input) as additional training data for retraining the sketch-analysis ML model 170 at a later time. The method 600 can then be repeated for each user input that is received comprising a sketch file 264.

### Training and Retraining the Sketch-Analysis ML Model

As discussed above, the sketch-analysis ML model 170 is trained to receive as input a sketch illustrating at least one intended object and containing one or more contextual features for the at least one intended object that indicate an identity of the at least one intended object. The sketch-analysis ML model 170 is further trained to analyze the one or more contextual features for the at least one intended object to specifically identity the at least one intended object illustrated in the sketch, and output object information 202 associated with the at least one intended object.

FIG. 7 sets forth a flow diagram of method steps for training and retraining a sketch-analysis machine learning model, according to various embodiments. Although the method steps are described with reference to the systems of FIGS. 1-5, persons skilled in the art will understand that any system configured to implement the method steps, in any order, falls within the scope of the embodiments. In some embodiments, the method 700 is executed in conjunction with a sketch analysis method 600 described in relation to FIG. 6 comprising an inference phase of the sketch-analysis ML model 170 for identifying one or more intended objects within a sketch.

As shown, the method 700 begins at step 710, where the server device 160 generates and/or receives a set of initial training data for training the sketch-analysis ML model 170. For example, the server device 160 can receive at least a portion of the set of initial training data from one or more remote servers 194 that store, for example, webpages including sketches of objects and the identities of the objects (labels/tags). As another example, the server device 160 can generate at least a portion of the set of initial training data by computer-generating imitations of hand-drawn sketches and providing labels/tags for the sketches.

The set of initial training data comprises ground-truth training data including sketches and associated meanings. In particular, the set of initial training data includes a set of sketches with associated labels/tags. Each sketch in the set of sketches includes an illustration of at least one object and one or more contextual features for the at least one object, such as an orientation, size/scale, and/or placement/location of the at least one object. A sketch in the set of sketches can illustrate an object via a drawn shape that represents the object, the drawn shape having one or more contextual features that indicate the identity of the object. For example, a sketch in the set of sketches can comprise the kitchen sketch 300 of FIG. 3 that includes a first drawn shape 310 representing a ceiling fan, a second drawn shape 320 representing a window fan, and a third drawn shape 330 representing a blender blade. In other embodiments, a sketch in the set of sketches can illustrate an object via a drawn text that represents the object, the drawn text having one or more contextual features that indicate the identity of the object. For example, a sketch in the set of sketches can comprise the car sketch 500 of FIG. 5 that includes a first drawn text 510 representing an automobile radio antenna, a second drawn text 520 representing an automobile rim and tire, and a third drawn text 530 representing an automobile exhaust pipe. Each sketch in the set of sketches has an associated label/tag that specifies the correct identity of the at least one object within the sketch, such as “ceiling fan,” “window fan,” “blender blade,” “automobile radio antenna,” “automobile rim and tire,” “automobile exhaust pipe,” and the like.

The server device 160 then trains (at step 720) the sketch-analysis ML model 170 based on the set of initial training data to identify objects within sketches based on contextual features. In some embodiments, the sketch-analysis ML model 170 comprises a convolutional neural network, image captioning model, and/or a large language model. In other embodiments, the sketch-analysis ML model 170 comprises another type of AI model, ML model, or any other large neural network. The server device 160 then executes (at step 730) the sketch-analysis ML model 170 in an inference/runtime phase comprising receiving sketches as input, processing the sketches to generate identifications of the objects within sketches based on contextual features, and receiving feedback user input (labels/tags) indicating whether the identifications of the objects within the is correct or not, which are each stored to a design history 182 on the server device 160.

The server device 160 then generates and/or receives (at step 740) a set of additional training data for retraining the sketch-analysis ML model 170. For example, the server device 160 can receive at least a portion of the set of additional training data from the design history 182 and/or from the one or more remote servers 194. As another example, the server device 160 can generate at least a portion of the set of additional training data by computer-generating imitations of hand-drawn sketches and providing labels/tags for the sketches. The server device 160 then retrains (at step 750) the sketch-analysis ML model 170 based on the set of additional training data to improve the accuracy of the sketch-analysis ML model 170 in identifying objects within sketches based on contextual features (increase the probability that the sketch-analysis ML model 170 identifies the correct objects within the sketches). Therefore, the server device 160 generates an improved sketch-analysis ML model 170 at step 750. The method 700 then continues at step 730 where the server device 160 executes the improved sketch-analysis ML model 170 in another inference/runtime phase. In this manner, the server device 160 generates an improved sketch-analysis ML model 170 at each iteration of the method 700.

In alternative embodiments, the sketch-analysis ML model 170 is trained to describe the overall content of a sketch image in text/words, such as describing the sketch image as a kitchen, car, house, and the like. In some embodiments, the sketch-analysis ML model 170 is further trained to disambiguate and identify/recognize specific objects/parts within the sketch image based on context-based features/characteristics of the specific objects/parts. The context-based features/characteristics can include the orientation, size/scale, and/or placement of the objects/parts within the sketch image.

In alternative embodiments, the sketch-analysis ML model 170 can comprise an image captioning model and a large language model that are further trained to perform the functions described herein. A image captioning model can be further trained to convert sketch images to text descriptions based on contextual features in the sketch images to identify what parts are in the sketch images and the orientation, size/scale, and/or placement of the parts within the sketch images, such as “a large fan on the ceiling pointing downwards,” “a medium fan on the wall parallel to the wall,” or “a small fan on the table parallel to the table.” The large language model can be further trained to identify the specific object/part described in text description that is output by the image captioning model. For example, the large language model can be further trained to determine what types of large fans are on the ceiling pointing downwards, what type of medium fans are on the wall parallel to the wall, or what types of small fans are on the table parallel to the table. In other embodiments, the sketch-analysis ML model 170 comprises another type of AI model, ML model, or any other large neural network that is trained to perform the above functions.

Implementing the sketch-analysis ML model 170 as a large neural network, such as a large language model that can be trained on billions of webpages and documents, the sketch-analysis ML model 170 can advantageously achieve capabilities that the sketch-analysis ML model 170 was not explicitly trained for and infer information based on real-world understanding and knowledge. This in turn advantageously improves the accuracy of the sketch-analysis ML model 170 in identifying intended objects in sketches, and advantageously avoids the need for the user to specify an abundance of details about the sketches and the objects illustrated therein.

### System Implementation

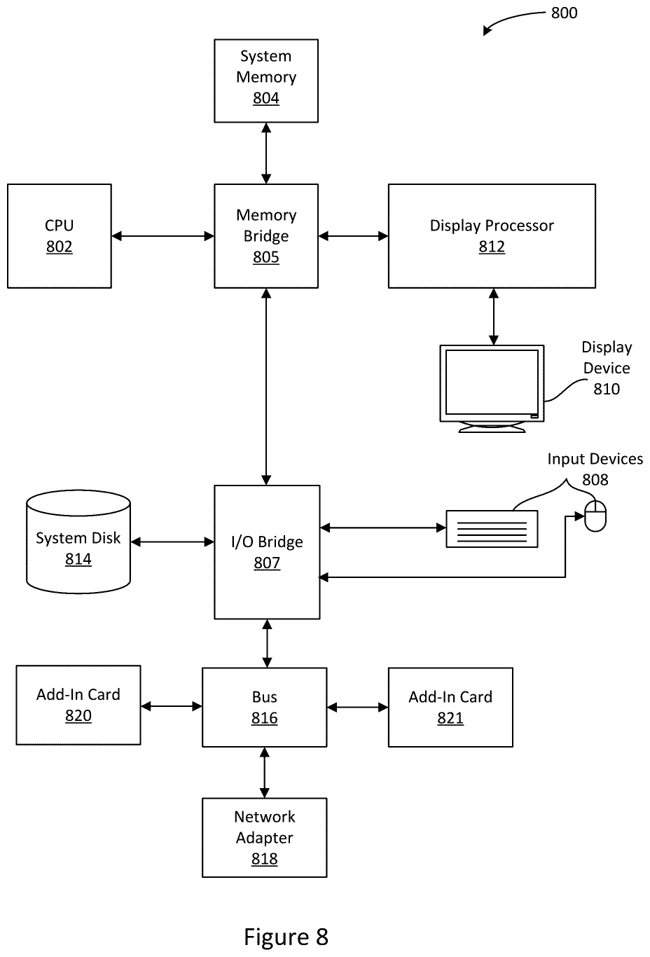

FIG. 8 depicts one architecture of a system 800 within which the various embodiments may be implemented. In some embodiments, the client device 110 and the server device 160 of FIG. 1 can each be implemented as a system 800 described herein. This figure in no way limits or is intended to limit the scope of the present disclosure. In various implementations, system 800 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 800 may be coupled together to practice one or more aspects of the present disclosure.

As shown, system 800 includes a central processing unit (CPU) 802 and a system memory 804 communicating via a bus path that may include a memory bridge 805. CPU 802 includes one or more processing cores, and, in operation, CPU 802 is the master processor of system 800, controlling and coordinating operations of other system components. System memory 804 stores software applications and data for use by CPU 802. CPU 802 runs software applications and optionally an operating system. Memory bridge 805, which may be, e.g., a Northbridge chip, is connected via a bus or other communication path (e.g., a HyperTransport link) to an I/O (input/output) bridge 807. I/O bridge 807, which may be, e.g., a Southbridge chip, receives user input from one or more user input devices 808 (e.g., keyboard, mouse, joystick, digitizer tablets, touch pads, touch screens, still or video cameras, motion sensors, and/or microphones) and forwards the input to CPU 802 via memory bridge 805.

A display processor 812 is coupled to memory bridge 805 via a bus or other communication path (e.g., a PCI Express, Accelerated Graphics Port, or HyperTransport link); in one embodiment display processor 812 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 804.

Display processor 812 periodically delivers pixels to a display device 810 (e.g., a screen or conventional CRT, plasma, OLED, SED or LCD based monitor or television). Additionally, display processor 812 may output pixels to film recorders adapted to reproduce computer generated images on photographic film. Display processor 812 can provide display device 810 with an analog or digital signal. In various embodiments, one or more of the various graphical user interfaces set forth in Appendices A-J, attached hereto, are displayed to one or more users via display device 810, and the one or more users can input data into and receive visual output from those various graphical user interfaces.

A system disk 814 is also connected to I/O bridge 807 and may be configured to store content and applications and data for use by CPU 802 and display processor 812. System disk 814 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 816 provides connections between I/O bridge 807 and other components such as a network adapter 818 and various add-in cards 820 and 821. Network adapter 818 allows system 800 to communicate with other systems via an electronic communications network, and may include wired or wireless communication over local area networks and wide area networks such as the Internet.

Other components (not shown), including USB or other port connections, film recording devices, and the like, may also be connected to I/O bridge 807. For example, an audio processor may be used to generate analog or digital audio output from instructions and/or data provided by CPU 802, system memory 804, or system disk 814. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 812 incorporates circuitry optimized for graphics and video processing, including, for example, video output circuitry, and constitutes a graphics processing unit (GPU). In another embodiment, display processor 812 incorporates circuitry optimized for general purpose processing. In yet another embodiment, display processor 812 may be integrated with one or more other system elements, such as the memory bridge 805, CPU 802, and I/O bridge 807 to form a system on chip (SoC). In still further embodiments, display processor 812 is omitted and software executed by CPU 802 performs the functions of display processor 812.

Pixel data can be provided to display processor 812 directly from CPU 802. In some embodiments of the present disclosure, instructions and/or data representing a scene are provided to a render farm or a set of server computers, each similar to system 800, via network adapter 818 or system disk 814. The render farm generates one or more rendered images of the scene using the provided instructions and/or data. These rendered images may be stored on computer-readable media in a digital format and optionally returned to system 800 for display. Similarly, stereo image pairs processed by display processor 812 may be output to other systems for display, stored in system disk 814, or stored on computer-readable media in a digital format.

Alternatively, CPU 802 provides display processor 812 with data and/or instructions defining the desired output images, from which display processor 812 generates the pixel data of one or more output images, including characterizing and/or adjusting the offset between stereo image pairs. The data and/or instructions defining the desired output images can be stored in system memory 804 or graphics memory within display processor 812. In an embodiment, display processor 812 includes 3D rendering capabilities for generating pixel data for output images from instructions and data defining the geometry, lighting shading, texturing, motion, and/or camera parameters for a scene. Display processor 812 can further include one or more programmable execution units capable of executing shader programs, tone mapping programs, and the like.

Further, in other embodiments, CPU 802 or display processor 812 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 802, display processor 812, or one or more other processing devices or any combination of these different processors.

CPU 802, render farm, and/or display processor 812 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 800 may be a robot or robotic device and may include CPU 802 and/or other processing units or devices and system memory 804. In such embodiments, system 800 may or may not include other elements shown in FIG. 1. System memory 804 and/or other memory units or devices in system 800 may include instructions that, when executed, cause the robot or robotic device represented by system 800 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 804 is connected to CPU 802 directly rather than through a bridge, and other devices communicate with system memory 804 via memory bridge 805 and CPU 802. In other alternative topologies display processor 812 is connected to I/O bridge 807 or directly to CPU 802, rather than to memory bridge 805. In still other embodiments, I/O bridge 807 and memory bridge 805 might be integrated into a single chip. The particular components shown herein are optional; for instance, any number of add-in cards or peripheral devices might be supported. In some embodiments, switch 816 is eliminated, and network adapter 818 and add-in cards 820, 821 connect directly to I/O bridge 807.

In sum, the design exploration application 130 displays a design space 230 and a prompt space 220, and receives user input via the prompt space 220 comprising a sketch file 264 containing a sketch. The sketch illustrates at least one intended object and includes one or more contextual features for the at least one intended object that indicate the identity of the at least one intended object. The design exploration application 130 generates a prompt 260 including design intent text 262, the sketch file 264, and/or basic information 268 derived from the sketch or sketch file. The design exploration application 130 transmits the prompt 260 to the trained sketch-analysis ML model 170 which processes the prompt 260 to identify the at least one intended object within the received sketch based on the one or more contextual features for the at least one intended object. The trained sketch-analysis ML model 170 also generates object information 202 associated with each identified object within the sketch. The object information 202 for an identified object includes identification information that specifies the type of object and additional descriptive information for the identified object.

The trained sketch-analysis ML model 170 then selects one or more generative ML models 180, 190 for processing the object information 202 and transmits the object information 202 to the selected ML models 180, 190. The selected ML models 180, 190 receives the object information 202 as input and outputs/generates one or more design objects 270 based on the object information 202. In particular, the selected ML models 180, 190 outputs/generates one or more design objects 270 for each identified object specified in the object information 202. The design exploration application 130 receives and displays the one or more design objects 270 within the design space 230. The design exploration application 130 then receives another user input via the prompt space 220, the another user input comprising feedback indicating whether the displayed design objects 270 correctly correspond to the intended objects illustrated in the sketch. The design exploration application 130 transmits a second prompt 260 that includes the feedback user input to the server device 160. The server device 160 then stores the initial prompt (including the sketch file 264), the object information 202 describing the identified object, and the second prompt (including the feedback user input) as additional training data for retraining the sketch-analysis ML model 170 at a later time.

At least one technical advantage of the disclosed techniques relative to the prior art is that the disclosed techniques provide an analysis of a sketch based on contextual features/characteristics included within the sketch to more accurately infer/identify intended objects within the sketch. In this regard, a sketch-analysis AI model can be trained to analyze the objects and contextual features/characteristics within different sketches, such as the orientation, size/scale, and/or placement/location of different objects illustrated within the sketches. During inferencing, the trained sketch-analysis AI model can then be used to identify one or more intended objects within a given input sketch. The identifications of the one or more intended objects can then be submitted to a downstream generative AI model that is trained to generate and return one or more design objects (such as 3D objects) corresponding to the one or more intended objects identified by and received from the trained sketch-analysis AI model. The one or more design objects can then be incorporated into an overall design (such as an overall 3D design). Accordingly, the disclosed techniques enable more accurate identification of intended objects illustrated in user sketches relative to what can be achieved using prior approaches. In this manner, the disclosed techniques can reduce or eliminate the need for the additional sketches and/or text prompts from the user that are commonly required with prior art approaches. These technical advantages provide one or more technological advancements over prior art approaches.

Aspects of the subject matter described herein are set out in the following numbered clauses.

1. In some embodiments, a computer-implemented method for performing an analysis of a sketch to identify one or more objects for a generative design comprises receiving the sketch via a user interference, executing a first trained machine learning (ML) model that generates an identification of a first object included in the sketch based on one or more contextual features that are associated with the first object and also are included in the sketch, transmitting the identification to a second machine learning model, and executing a second trained ML model that generates a first design object based on the identification.

2. The computer-implemented method of clause 1, wherein the one or more contextual features associated with the first object include at least one of an orientation, size, or location of the first object within the sketch.

3. The computer-implemented method of clauses 1 or 2, wherein the first object is illustrated within the sketch as a drawn shape.

4. The computer-implemented method of any of clauses 1-3, wherein the first object is represented by a drawn text that represents the first object.

5. The computer-implemented method of any of clauses 1-4, wherein the sketch comprises a hand-drawn illustration that is digitally captured in a sketch file.

6. The computer-implemented method of any of clauses 1-5, wherein the sketch comprises a digital illustration generated using a computer-based input device and captured in a sketch file.

7. The computer-implemented method of any of clauses 1-6, wherein the user interface includes a prompt space for interacting with the first trained ML model, and wherein the sketch is received in the prompt space.

8. The computer-implemented method of any of clauses 1-7, further comprising displaying the first design object within in a design space included within the user interface, and integrating the first design object into an overall design within the design space.

9. The computer-implemented method of any of clauses 1-8, wherein the design object comprises at least one of a two-dimensional object, a three-dimensional object, or an image.

10.The computer-implemented method of any of clauses 1-9, wherein the first trained ML model further generates a description of the first object that also is transmitted to the second ML model, and the second trained ML model generates the first design object further based on the description of the first object.

11. In some embodiments, one or more non-transitory computer-readable media include instructions that, when executed by one or more processors, cause the one or more processors to perform an analysis of a sketch to identify one or more objects for a generative design by performing the steps of receiving the sketch via a user interference, executing a first trained machine learning (ML) model that generates an identification of a first object included in the sketch based on one or more contextual features that are associated with the first object and also are included in the sketch, transmitting the identification to a second machine learning model, and executing a second trained ML model that generates a first design object based on the identification.

12. The one or more non-transitory computer-readable media of clause 11, wherein the one or more contextual features associated with the first object include at least one of an orientation, size, or location of the first object within the sketch.

13. The one or more non-transitory computer-readable media of clauses 11 or 12, wherein the first object is illustrated within the sketch as a drawn shape.

14. The one or more non-transitory computer-readable media of any of clauses 11-13, wherein the first object is represented by a drawn text that represents the first object.

15. The one or more non-transitory computer-readable media of any of clauses 11-14, wherein the sketch comprises a hand-drawn illustration that is digitally captured in a sketch file.

16. The one or more non-transitory computer-readable media of any of clauses 11-15, wherein the sketch comprises a digital illustration generated using a computer-based input device and captured in a sketch file.

17. The one or more non-transitory computer-readable media of any of clauses 11-16, wherein the one or more contextual features associated with the first object include an orientation of the first object relative to an orientation of a second object within the sketch.

18. The one or more non-transitory computer-readable media of any of clauses 11-17, wherein the one or more contextual features associated with the first object include a size of the first object relative to a size of a second object within the sketch.

19. The one or more non-transitory computer-readable media of any of clauses 11-18, wherein the one or more contextual features associated with the first object include a location of the first object relative to a location of a second object within the sketch.

20. In some embodiments, a system comprises one or more memories storing instructions, and one or more processors coupled to the one or more memories that, when executing the instructions to perform an analysis of a sketch to identify one or more objects for a generative design, perform the steps of receiving the sketch via a user interference, executing a first trained machine learning (ML) model that generates an identification of a first object included in the sketch based on one or more contextual features that are associated with the first object and also are included in the sketch, transmitting the identification to a second machine learning model, and executing a second trained ML model that generates a first design object based on the identification.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module” or “system.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon. The software constructs and entities (e.g., engines, modules, GUIs, etc.) are, in various embodiments, stored in the memory/memories shown in the relevant system figure(s) and executed by the processor(s) shown in those same system figures.

Any combination of one or more non-transitory computer readable medium or media may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for performing an analysis of a sketch to identify one or more objects for a generative design, the method comprising:
receiving the sketch via a user interference;
executing a first trained machine learning (ML) model that generates an identification of a first object included in the sketch based on one or more contextual features that are associated with the first object and also are included in the sketch;
transmitting the identification to a second machine learning model; and
executing a second trained ML model that generates a first design object based on the identification.

2. The computer-implemented method of claim 1, wherein the one or more contextual features associated with the first object include at least one of an orientation, size, or location of the first object within the sketch.

3. The computer-implemented method of claim 1, wherein the first object is illustrated within the sketch as a drawn shape.

4. The computer-implemented method of claim 1, wherein the first object is represented by a drawn text that represents the first object.

5. The computer-implemented method of claim 1, wherein the sketch comprises a hand-drawn illustration that is digitally captured in a sketch file.

6. The computer-implemented method of claim 1, wherein the sketch comprises a digital illustration generated using a computer-based input device and captured in a sketch file.

7. The computer-implemented method of claim 1, wherein the user interface includes a prompt space for interacting with the first trained ML model, and wherein the sketch is received in the prompt space.

8. The computer-implemented method of claim 1, further comprising:
displaying the first design object within in a design space included within the user interface; and
integrating the first design object into an overall design within the design space.

9. The computer-implemented method of claim 1, wherein the design object comprises at least one of a two-dimensional object, a three-dimensional object, or an image.

10. The computer-implemented method of claim 1, wherein:
the first trained ML model further generates a description of the first object that also is transmitted to the second ML model; and
the second trained ML model generates the first design object further based on the description of the first object.

11. One or more non-transitory computer-readable media including instructions that, when executed by one or more processors, cause the one or more processors to perform an analysis of a sketch to identify one or more objects for a generative design by performing the steps of:
receiving the sketch via a user interference;
executing a first trained machine learning (ML) model that generates an identification of a first object included in the sketch based on one or more contextual features that are associated with the first object and also are included in the sketch;
transmitting the identification to a second machine learning model; and
executing a second trained ML model that generates a first design object based on the identification.

12. The one or more non-transitory computer-readable media of claim 11, wherein the one or more contextual features associated with the first object include at least one of an orientation, size, or location of the first object within the sketch.

13. The one or more non-transitory computer-readable media of claim 11, wherein the first object is illustrated within the sketch as a drawn shape.

14. The one or more non-transitory computer-readable media of claim 11, wherein the first object is represented by a drawn text that represents the first object.

15. The one or more non-transitory computer-readable media of claim 11, wherein the sketch comprises a hand-drawn illustration that is digitally captured in a sketch file.

16. The one or more non-transitory computer-readable media of claim 11, wherein the sketch comprises a digital illustration generated using a computer-based input device and captured in a sketch file.

17. The one or more non-transitory computer-readable media of claim 11, wherein the one or more contextual features associated with the first object include an orientation of the first object relative to an orientation of a second object within the sketch.

18. The one or more non-transitory computer-readable media of claim 11, wherein the one or more contextual features associated with the first object include a size of the first object relative to a size of a second object within the sketch.

19. The one or more non-transitory computer-readable media of claim 11, wherein the one or more contextual features associated with the first object include a location of the first object relative to a location of a second object within the sketch.

20. A system comprising:
one or more memories storing instructions; and
one or more processors coupled to the one or more memories that, when executing the instructions to perform an analysis of a sketch to identify one or more objects for a generative design, perform the steps of:
receiving the sketch via a user interference;
executing a first trained machine learning (ML) model that generates an identification of a first object included in the sketch based on one or more contextual features that are associated with the first object and also are included in the sketch;
transmitting the identification to a second machine learning model; and
executing a second trained ML model that generates a first design object based on the identification.
